(19) United States
(12) Patent Application Publication
(10) Pub. No.: US 2015/0103856 A1
(43) Pub. Date: Apr. 16, 2015

(54) NITRIDE SEMICONDUCTOR LIGHT EMITTING DEVICE

(71) Applicant: PANASONIC INTELLECTUAL PROPERTY MANAGEMENT CO., LTD., Osaka (JP)

(72) Inventors: Hiroyuki HAGINO, Osaka (JP); Shinji YOSHIDA, Shiga (JP); Kiyoshi MORIMOTO, Osaka (JP)

(21) Appl. No.: 14/580,190

(22) Filed: Dec. 22, 2014

Related U.S. Application Data
(63) Continuation of application No. PCT/JP2013/000903, filed on Feb. 19, 2013.

(30) Foreign Application Priority Data
Jul. 11, 2012 (JP) 2012-155302

(51) Int. Cl. H01S 5/022; H01S 5/343; H01S 5/024; H01S 5/40

(52) U.S. Cl. CPC H01S 5/02212; H01S 5/02228; H01S 5/02244; H01S 5/02276; H01S 5/4025; H01S 5/34333; H01S 5/02469
USPC 372/44.01

(57) ABSTRACT

A nitride semiconductor light emitting device includes a nitride semiconductor light emitting element and a package in which the nitride semiconductor light emitting element is accommodated. The package includes a base table in which openings are formed, a cap defining an accommodation space for accommodating the nitride semiconductor light emitting element together with the base table, lead pins passing through the openings and electrically connected to the nitride semiconductor light emitting element, and insulating members embedded in the openings to insulate the base table from the lead pins. At least parts of the insulating members which are located on an accommodation space side are made of a first insulating material containing no Si—O bond.

### CROSS-REFERENCE TO RELATED APPLICATIONS

This is a continuation of International Application No. PCT/JP2013/000903 filed on Feb. 19, 2013, which claims priority to Japanese Patent Application No. 2012-155302 filed on Jul. 11, 2012. The entire disclosures of these applications are incorporated by reference herein.

### BACKGROUND

The present disclosure relates to nitride semiconductor light emitting devices.

Nitride semiconductor light emitting devices including a nitride semiconductor light emitting element, such as a semiconductor laser element have been actively developed as a light source of an image display device, such as a laser display and a projector, and a light source of processing equipment for industrial use, such as a laser welding device, a laser scribing device, and a thin film annealing device. Outgoing light of such a nitride semiconductor light emitting element has a wavelength in the range of blue light to ultraviolet light, and emits very high energy light whose optical output exceeds 1 W.

Various types of structures of packages to which semiconductor laser elements are mounted have been proposed. For example, Japanese Unexamined Patent Publication No. 2005-354099 discloses a lead frame-type package structure. This package provides electric interconnects by resin molding of lead frames made of metal, but a semiconductor laser element is not fully hermetically sealed off from the outside air. In contrast, Japanese Unexamined Patent Publication No. H07-335966, Japanese Unexamined Patent Publication No. 2009-135235, Japanese Unexamined Patent Publication No. 2001-326002, and Japanese Unexamined Patent Publication No. 2004-289010 disclose a package structure in which a semiconductor laser element is hermetically sealed off from the outside air. For example, Japanese Unexamined Patent Publication No. H07-335966 discloses a so-called butterfly-type package structure. The butterfly-type package structure is a matched seal-type structure including an insulating member and a metal member covering a semiconductor laser, wherein the insulating member and the metal member are made of materials whose thermal expansion coefficients are approximately equal to each other to facilitate hermetic sealing. On the other hand, for example, Japanese Unexamined Patent Publication No. 2009-135235, Japanese Unexamined Patent Publication No. 2001-326002, and Japanese Unexamined Patent Publication No. 2004-289010 disclose a so-called CAN-type package structure. The CAN-type package structure is a compression seal-type structure in which lead pins serving as electric interconnects and an insulating member (glass) near the lead pins are compressed by a fixing body made of metal due to a difference in thermal expansion coefficient, thereby ensuring hermeticity.

There are various package structures as described above, but a hermetic package is preferable for nitride semiconductor light emitting devices because organic substances in the outside air deteriorate the characteristics of nitride semiconductor light emitting elements. Thus, in recent years, the CAN-type hermetic package structure has been widely used for developing nitride semiconductor light emitting devices whose optical output exceeds 1 watt. However, the package structure of this type requires devices to improve heat dissipation and reliability.

With reference to FIG. 14, the structure of a conventional nitride semiconductor light emitting device described in Japanese Unexamined Patent Publication No. 2004-289010 will be described below. A nitride semiconductor light emitting device 1000 includes a semiconductor laser element 1101 mounted to a submount 1106 and a CAN package 1102. The CAN package 1102 includes a fixing body 1103 for fixing the semiconductor laser element 1101 at a predetermined position, and a cap 1104 covering the semiconductor laser element 1101 fixed to the fixing body 1103. The fixing body 1103 has a disc shape, and a principal surface of the fixing body 1103 is provided with a post 1105. The submount 1106, which is made of Si or MN, is attached to the post 1105 by Ag paste. The semiconductor laser element 1101 having a wavelength of 405 nm band is attached to the submount 1106 by solder made of AuSn, or the like. The fixing body 1103 is provided with lead pins 1107a, 1107b, 1107c made of a conductive material. The lead pin 1107a is electrically connected to the post 1105. The lead pins 1107b, 1107c are connected to the submount 1106 and the semiconductor laser 1101, respectively or to the semiconductor laser 1101 and the submount 1106, respectively by wires 1108. An insulating spacer (not shown) made of low-melting glass is provided between the fixing body 1103 and the lead pins 1107b, 1107c. On the other hand, the cap 1104 has a cylindrical shape having a closed end and an opening to which the fixing body 1103 is adhered. At the end opposite to the opening, a light extraction section 1109 is provided to extract a laser beam emitted from the semiconductor laser element 1101. The light extraction section 1109 has a circular shape and is covered with a sealing glass 1110 made of glass including high-transmittance fused quartz as a base material. With this configuration, the lead pins 1107b, 1107c are electrically insulated from the fixing body 1103, and thus it is intended to easily supply electric power through the lead pins to the semiconductor laser element 1101, and to prevent air from entering the CAN package 1102.

Such a package structure is desirably made of a material whose thermal conductivity is as high as possible in order to improve heat dissipation with hermeticity being maintained. Therefore, it has been proposed to use iron or copper having a high thermal conductivity as a material of the post to which a nitride semiconductor light emitting element is mounted or a base. Japanese Unexamined Patent Publication No. 2001-326002 also proposes a method for fabricating an insulating member including a plurality of types of glass having different thermal expansion coefficients in order to prevent a hermeticity reduction which occurs when copper is used as a material of a stem.

On the other hand, concerning reliability improvement, Japanese Unexamined Patent Publication No. 2004-289010 describes that when the above-described semiconductor package structure is applied to a semiconductor laser element having a wavelength of 405 nm band, a deposit is formed on a light-outgoing end facet, which deteriorates the characteristics of the semiconductor laser. When an adhesive including an organic substance, for example, Ag paste is used in a conventional package structure, the adhesive generates a volatile gas containing a Si organic compound gas, so that the volatile gas is present in the package at a certain steam pressure. When the volatile gas is irradiated with a laser beam from the semiconductor laser element, optical energy cuts bonds of Si organic compound gas molecules, so that a compound of Si and O is deposited in the package. The reaction probability of decomposing reaction caused by the energy (about 3.0 eV) of one photon in the 405 nm band is very low. However, Japanese Unexamined Patent Publication No. 2004-289010 describes that decomposition of the Si organic compound gas is caused by a multiphoton absorption process typified by a 2-photon absorption process. Multiphoton absorption process is more likely to occur when the optical intensity is higher. Thus, the decomposition of the Si organic compound gas is likely to occur at the light-outgoing end facet of the semiconductor laser element because the optical intensity is maximum at the light-outgoing end facet. Thus, the decomposition of the Si organic compound gas is promoted at the light-outgoing end facet, and deposition of the compound of Si and O progresses. Japanese Unexamined Patent Publication No. 2004-289010 describes using an adhesive containing no organic substance to connect a submount to a fixing body or limiting the amount of a used organic substance adhesive to a certain value or less as a method to reduce the deterioration of the characteristics of the semiconductor laser element caused by the deposition of such a compound.

### SUMMARY

However, the present inventors found that when a semiconductor laser whose optical output exceeds 1 watt is used in a nitride semiconductor light emitting device using the conventional package as described above, the Si compound is deposited on the light-outgoing end facet and the characteristics are deterioration even when no organic adhesive is used for the semiconductor package.

The present disclosure is directed generally to a nitride semiconductor light emitting device in which a nitride semiconductor light emitting element is hermetically enclosed, wherein deterioration of the characteristics of the nitride semiconductor light emitting element is alleviated.

A nitride semiconductor light emitting device of the present disclosure includes: a nitride semiconductor light emitting element; and a package in which the nitride semiconductor light emitting element is accommodated. The package includes a base table which holds the nitride semiconductor light emitting element and in which an opening is formed; a cap fixed to the base table to define an accommodation space for accommodating the nitride semiconductor light emitting element together with the base table, a lead pin passing through the opening and electrically connected to the nitride semiconductor light emitting element, and an insulating member filled in the opening to insulate the base table from the lead pin. At least part of the insulating member which is located on an accommodation space side is made of a first insulating material containing no Si—O bond.

With this configuration, it is possible to limit entry of a desorption gas containing Si into the package, so that deterioration of the characteristics of the nitride semiconductor light emitting element can be reduced.

In the nitride semiconductor light emitting device of the present disclosure, the first insulating material is preferably a resin.

With this configuration, the insulating member can be easily formed.

In the nitride semiconductor light emitting device of the present disclosure, the first insulating material preferably has a heat resistant temperature of 300° C. or higher.

With this configuration, deterioration of the insulating material due to a high temperature during a mounting step of the semiconductor laser can be reduced, so that it is possible to limit the entry of the desorption gas.

In the nitride semiconductor light emitting device of the present disclosure, the first insulating material may be polyimide.

With this configuration, it is possible to limit the entry of the desorption gas containing Si into the package, so that deterioration of the characteristics of the nitride semiconductor light emitting element can be reduced.

In the nitride semiconductor light emitting device of the present disclosure, the insulating member may include a first insulating member made of the first insulating material and a second insulating member made of glass, and on the accommodation space side, the first insulating member may cover the second insulating member.

In the nitride semiconductor light emitting device of the present disclosure, the opening may have a first portion on the accommodation space side and a second portion whose diameter is smaller than a diameter of the first portion, and the first insulating member may be embedded in the first portion, and the second insulating member may be embedded in the second portion.

With this configuration, steps for fabricating the nitride semiconductor light emitting device can be simplified.

In the nitride semiconductor light emitting device of the present disclosure the base table is preferably made of oxygen-free copper.

With this configuration, the heat dissipation of the nitride semiconductor light emitting device can be improved.

According to the nitride semiconductor light emitting device of the present disclosure, it is possible to reduce deterioration of the characteristics of a nitride semiconductor light emitting element in a nitride semiconductor light emitting device in which the nitride semiconductor light emitting element is hermetically enclosed.

### BRIEF DESCRIPTION OF THE DRAWINGS

FIG. 1A is a perspective view illustrating a nitride semiconductor light emitting device according to a first example.

FIG. 1B is an exploded perspective view illustrating the nitride semiconductor light emitting device according to the first example.

FIG. 2A is a cross-sectional view illustrating the nitride semiconductor light emitting device of the first example taken along the line Ia-Ia.

FIG. 2B is a cross-sectional view illustrating the nitride semiconductor light emitting device of the first example taken along the line Ib-Ib.

FIG. 3A is a view illustrating a step of a method for fabricating the nitride semiconductor light emitting device according to the first example.

FIG. 3B is a view illustrating a step of the method for fabricating the nitride semiconductor light emitting device according to the first example.

FIG. 3C is a view illustrating a step of the method for fabricating the nitride semiconductor light emitting device according to the first example.

FIG. 3D is a view illustrating a step of the method for fabricating the nitride semiconductor light emitting device according to the first example.

FIG. 3E is a view illustrating a step of the method for fabricating the nitride semiconductor light emitting device according to the first example.

FIG. 4 is a table illustrating results of evaluation of the nitride semiconductor light emitting device according to the first example and nitride semiconductor light emitting devices of comparative examples.

FIG. 5A is a view illustrating optical output of the nitride semiconductor light emitting device of the comparative example during in the case of continuous operation.

FIG. 5B is a view illustrating optical output of the nitride semiconductor light emitting device according to the first example in the case of continuous operation.

FIG. 6A is a table illustrating the characteristics of materials included in a shield member.

FIG. 6B is a table illustrating a comparison between methods for forming the shield member.

FIG. 6C is a table illustrating a comparison between materials included in an adhesive layer.

FIG. 7 is a cross-sectional view illustrating a nitride semiconductor light emitting device according to a first variation of the first example.

FIG. 8 is a cross-sectional view illustrating a nitride semiconductor light emitting device according to a second variation of the first example.

FIG. 9 is a cross-sectional view illustrating a nitride semiconductor light emitting device according to a second example.

FIG. 10 is a view illustrating a step of a method for fabricating the nitride semiconductor light emitting device according to the second example.

FIG. 11A is an exploded perspective view illustrating a nitride semiconductor light emitting device according to a third example.

FIG. 11B is a cross-sectional view illustrating the nitride semiconductor light emitting device according to the third example.

FIG. 12A is an exploded perspective view illustrating a nitride semiconductor light emitting device according to a fourth example.

FIG. 12B is a perspective view illustrating a part of the nitride semiconductor light emitting device according to the fourth example.

FIG. 12C is a top view illustrating a part of the nitride semiconductor light emitting device according to the fourth example.

FIG. 13A is a cross-sectional view illustrating the nitride semiconductor light emitting device according to the fourth example.

FIG. 13B is a cross-sectional view illustrating a part of the nitride semiconductor light emitting device according to the fourth example.

FIG. 14 is a view illustrating a configuration of a conventional semiconductor light emitting device.

### DETAILED DESCRIPTION

### First Example

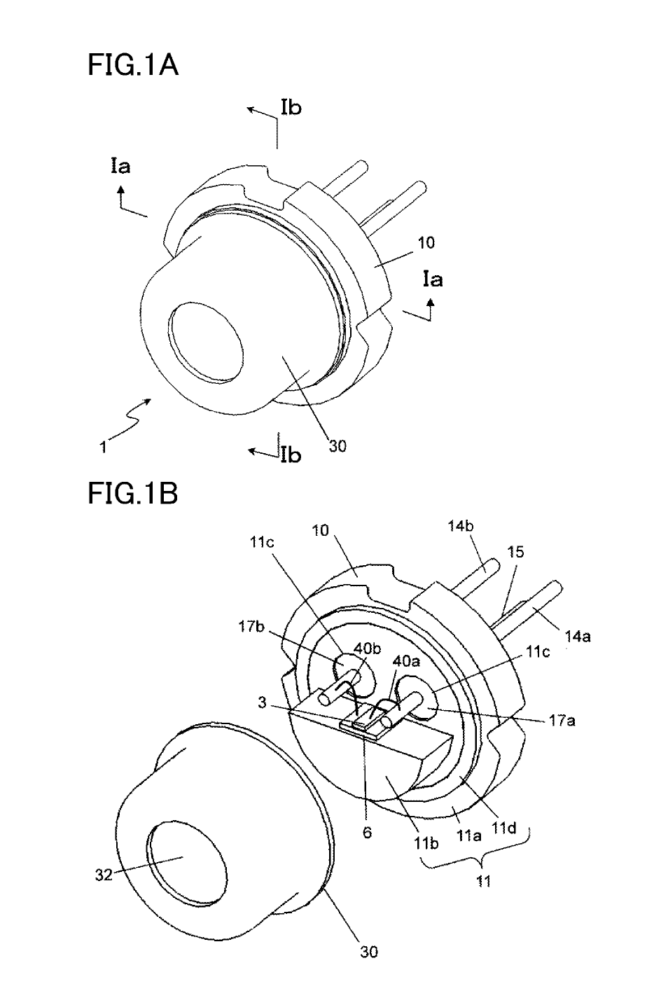

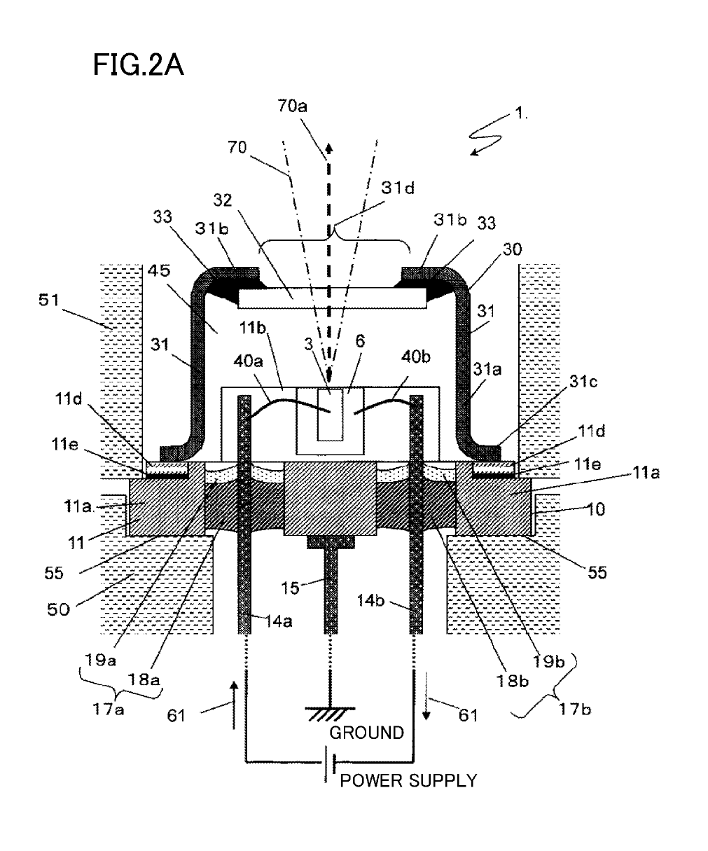

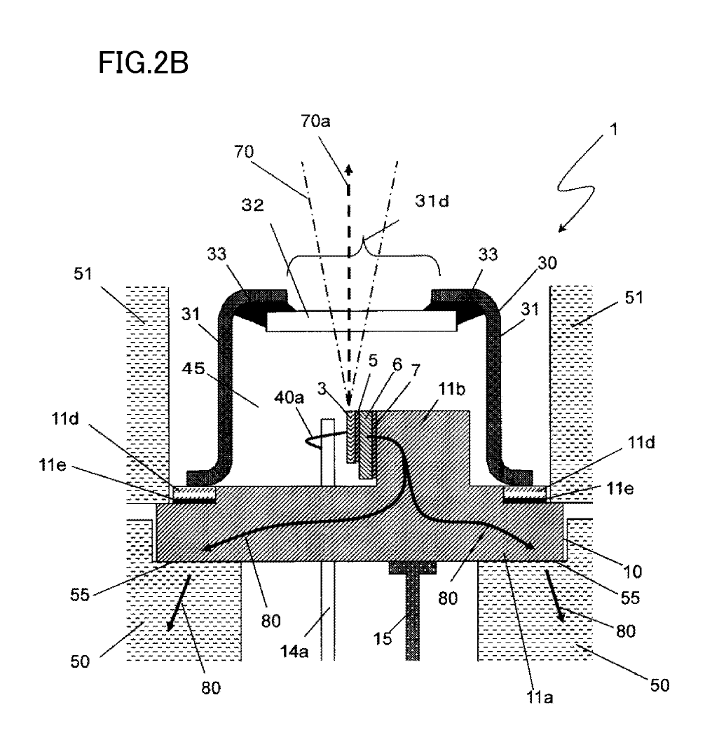

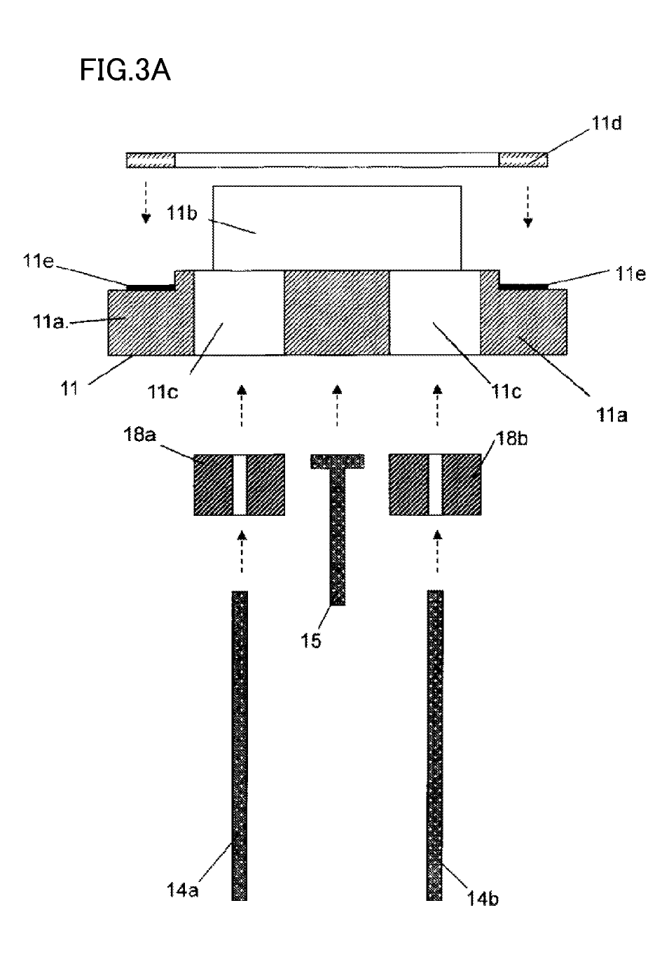

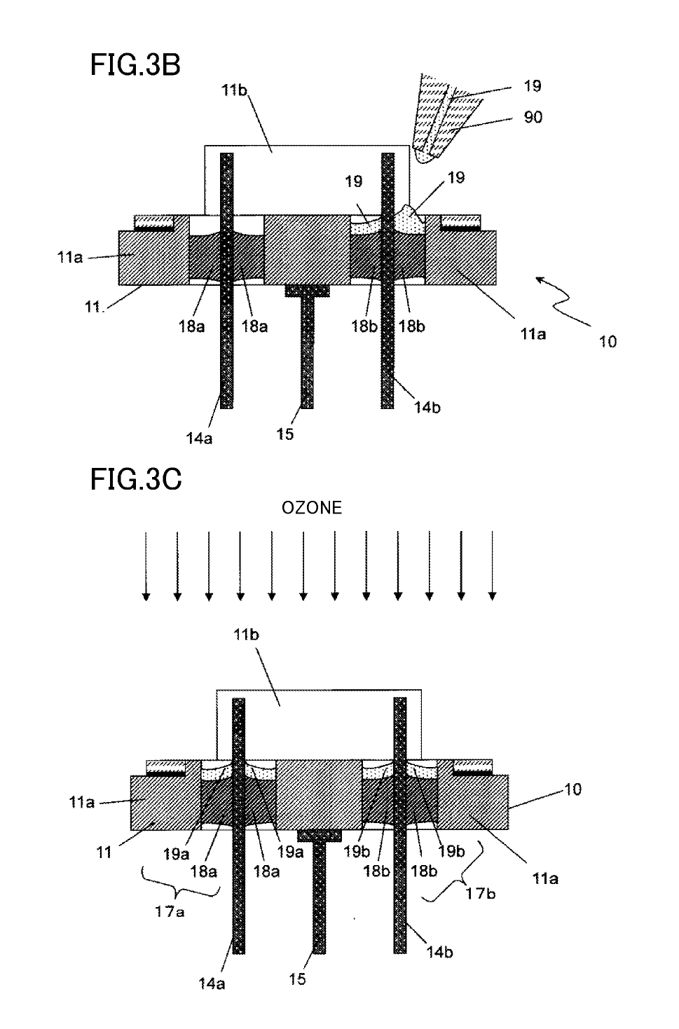

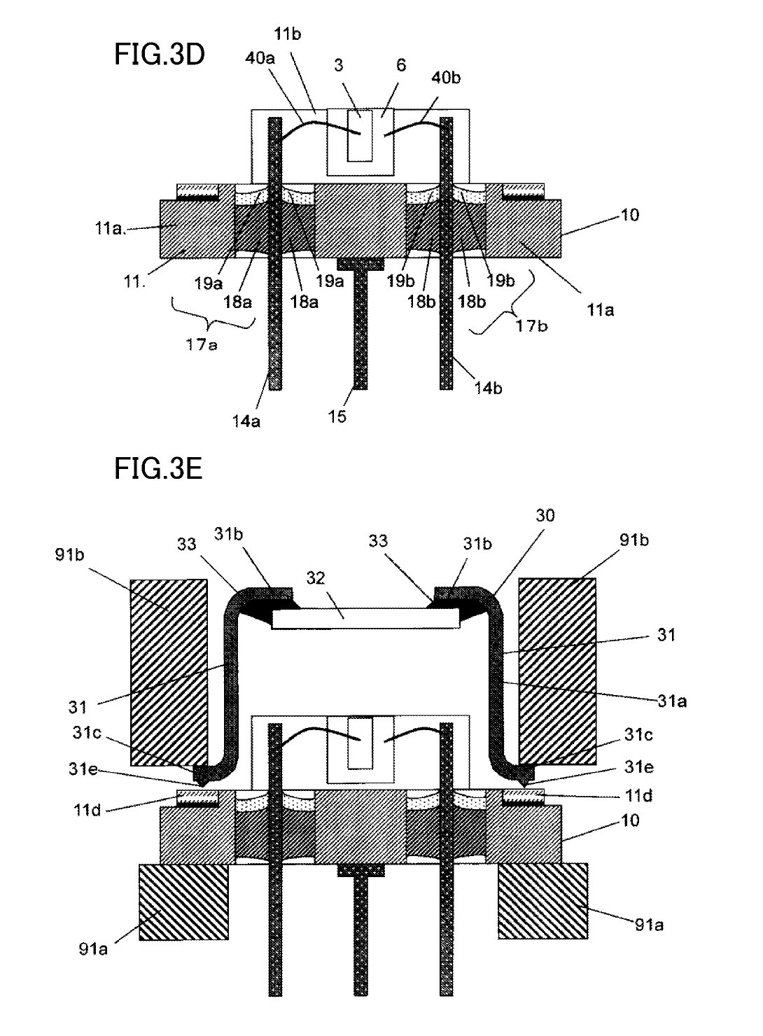

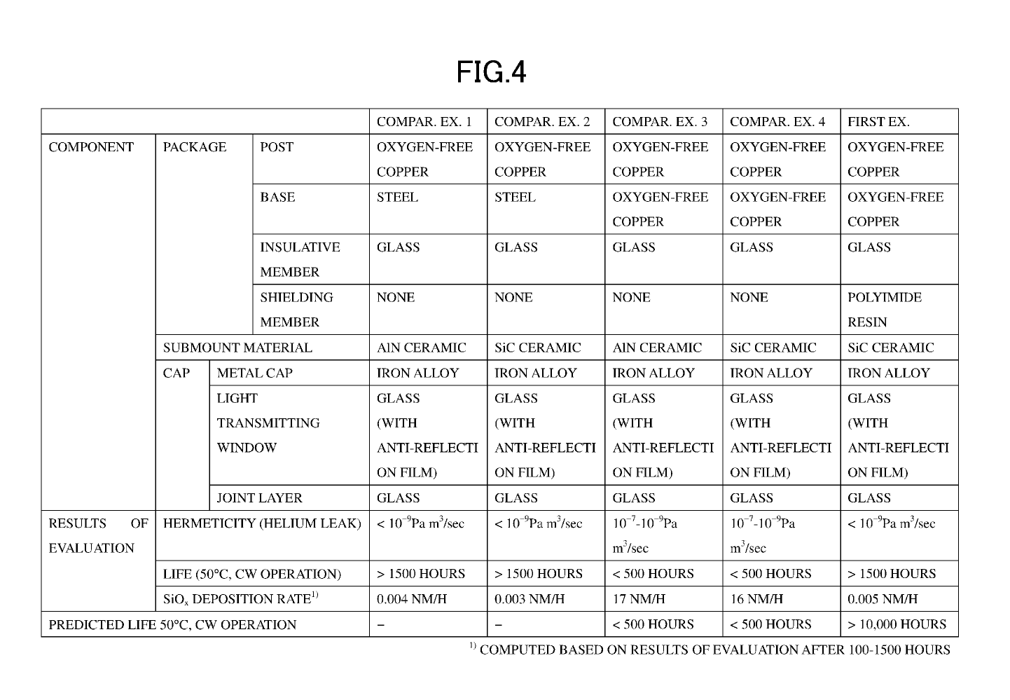

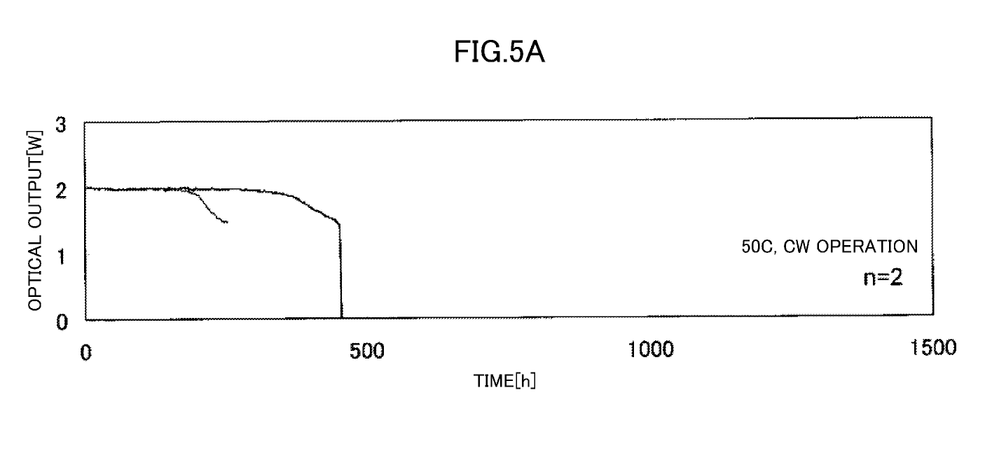

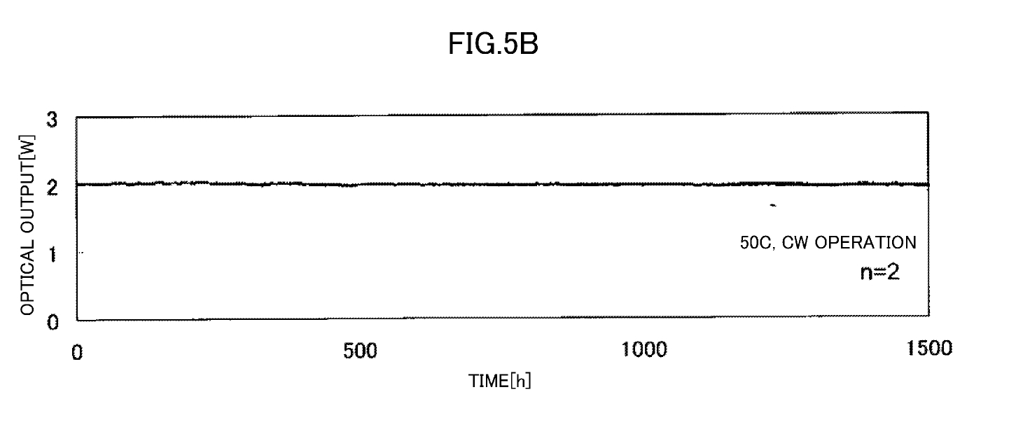

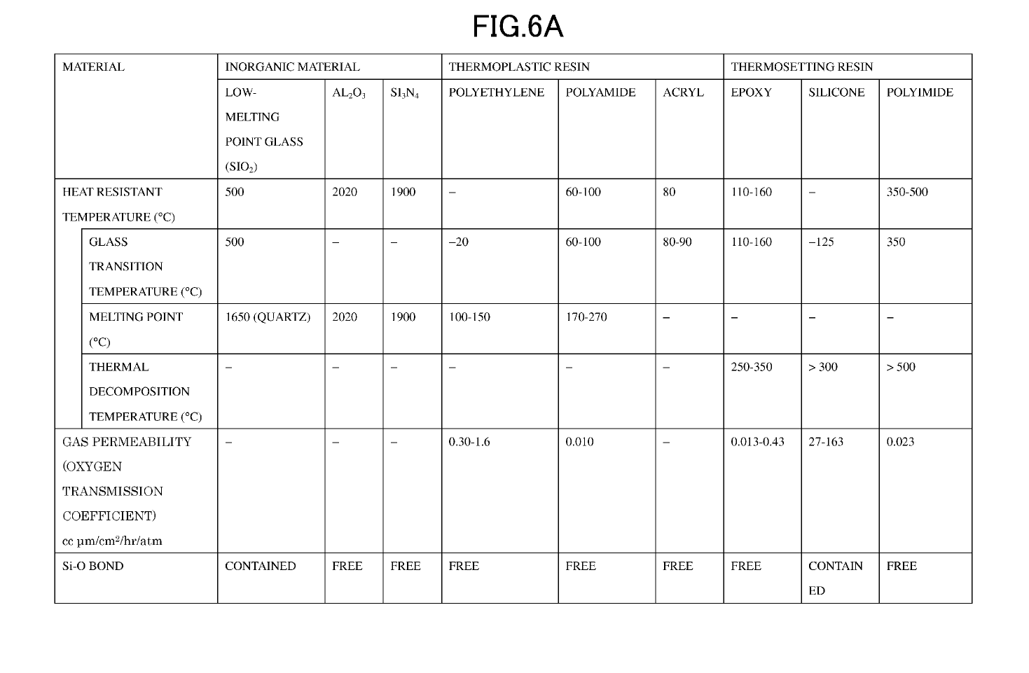

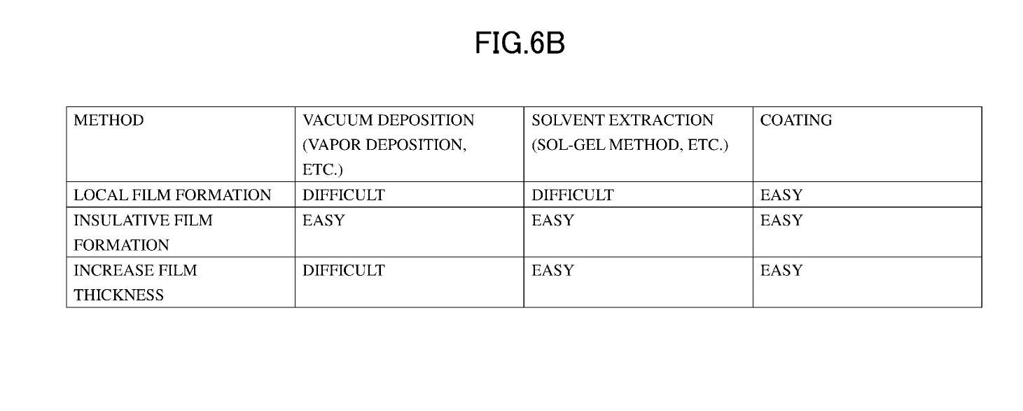

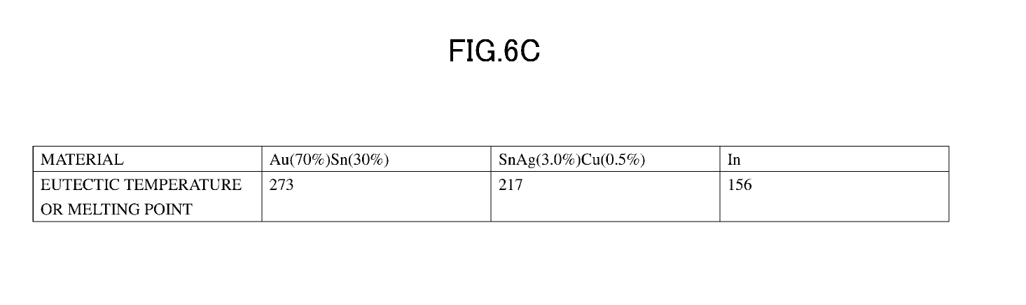

A first example will be described with reference to FIGS. 1A-1B, 2A-2B, 3A-3E, 4, 5A-5B, 6A-6C, 7, and 8. FIG. 1A is a perspective view illustrating a nitride semiconductor light emitting device of the present example, and FIG. 1B is an exploded perspective view illustrating the configuration of the nitride semiconductor light emitting device, wherein the nitride semiconductor light emitting device is disassembled into a cap 30 and a package 10. FIGS. 2A and 2B are schematic cross-sectional views illustrating the configuration and the operation of the nitride semiconductor light emitting device of the present example in detail. FIGS. 3A-3E are views illustrating a method for fabricating the nitride semiconductor light emitting device of the present example. FIG. 4 is a table showing results of evaluation of the nitride semiconductor light emitting device according to the first example and nitride semiconductor light emitting devices of comparative examples. FIG. 5A is a view illustrating time-dependency of optical output of the nitride semiconductor light emitting device of the comparative example of FIG. 4 in the case of continuous operation. FIG. 5B is a view illustrating time-dependency of optical output of the nitride semiconductor light emitting device of the present example in the case of continuous operation. FIG. 6A is a table showing a list of shielding materials used in the present example. FIG. 6B is a table showing a list of fabrication method considered by comparison in the present example. FIG. 6C is a table showing comparison of materials for an adhesive layer used in the nitride semiconductor light emitting device of the present example.

As illustrated in the perspective view of FIG. 1A and the exploded perspective view of FIG. 1B, the package type of a nitride semiconductor light emitting device 1 of the present example is a so-called CAN-type. In the nitride semiconductor light emitting device 1, a nitride semiconductor light emitting element 3 is fastened to a post 11b of the package 10 via a submount 6, and the cap 30 is fixed to a base table 11 of the package 10. Thus, a nitride semiconductor light emitting element 3 is hermetically enclosed in a space (accommodation space) surrounded by the cap 30 and the base table 11.

FIG. 2A and FIG. 2B illustrate a state where the nitride semiconductor light emitting device 1 is fixed by a fixing tool 50 and a pressing tool 51 from front and rear sides. FIG. 2A is a view corresponding to the cross section taken along the line Ia-Ia of FIG. 1A, and FIG. 2B is a view corresponding to the cross section taken along the line Ib-lb of FIG. 1A. The package 10 includes the base table 11, lead pins 14a, 14b for electric connection, a ground lead pin 15, and insulating members 17a, 17b for electrically isolating the base table 11 from the lead pins 14a, 14b. The insulating member 17a includes a shield member 19a and a glass ring 18a, and the insulating member 17b includes a shield member 19b and a glass ring 18b. The shield members 19a, 19b serve as first insulating members. The glass ring 18a serves as a second insulating member for fixing the lead pin 14a to the base table 11, and the glass ring 18b serves as a second insulating member for fixing the lead pin 14b to the base table 11. The shield members 19a, 19b respectively cover the glass rings 18a, 18b. The base table 11 includes a disc-shaped base 11a, the post 11b for fixing a fabricated nitride semiconductor light emitting element 3 to a principal surface of the base 11a, a welding table 11d for fixing the cap 30 to the base 11a, and an adhesive layer 11e for adhering the welding table 11d to the base 11a. Openings 11c are formed in the base 11a to place the lead pins therein. Here, the base 11a and the post 11b are preferably made of iron (Fe) having high thermal conductivity, copper (Cu) having high thermal conductivity, an alloy thereof, or the like. Specifically, the present example will be described with reference to the base 11a and the post 11b which are integrally molded from oxygen-free copper having high thermal conductivity. Here, the welding table 11d is made of, for example, a Fe:Ni alloy (e.g., 42 alloy), Kovar, or the like, and the adhesive layer 11e is made of, for example, silver solder, or the like. The glass rings 18a, 18b are made of low-melting point glass obtained by adding modifying oxide such as barium oxide to silicon oxide (SiO₂ or SiOₓ). The shield members 19a, 19b are made of an insulating material, such as a polyimide resin, having high gas barrier properties and heat resistance, and containing no Si—O bond. The ground lead pin 15 is fixed to the base 11a by welding or silver soldering, so that the ground lead pin 15 is electrically connected to the base 11a. A surface of the package is plated with, for example, Ni, Au to prevent oxidation.

As illustrated in FIG. 2B, the nitride semiconductor light emitting element 3 is fastened to a mounting surface of the post 11b of the base table 11 having the above-described configuration via the submount 6 made of, for example, SiC ceramic or AlN ceramic. Here, the nitride semiconductor light emitting element 3 includes a first nitride semiconductor layer, a light-emitting layer, and a second nitride semiconductor layer which are stacked on a substrate by a crystal growth technique. The first nitride semiconductor layer has a stacked structure including, for example, an n-type buffer layer, an n-type clad layer, and an n-type guide layer. The light-emitting layer includes a multiple quantum well made of, for example, InGaN and GaN. The second nitride semiconductor layer has a stacked structure including, for example, a p-type guide layer and a p-type clad layer. The substrate is made of, for example, n-type GaN. On upper and lower surfaces of the nitride semiconductor light emitting element 3, electrodes made of a metal multilayer film containing any metal of Pd, Pt, Ti, Ni, Al, W, Au, and the like are formed, and the nitride semiconductor light emitting element 3 is fastened to the submount 6 via an adhesive layer 5 which is, for example, Au(70%)Sn(30%) solder. Here, on upper and lower surfaces of the submount 6, metal multilayer films made of, for example, Ti/Pt/Au are formed, and the nitride semiconductor light emitting element 3 is fastened to the submount 6 via the adhesive layer 5, and the submount 6 is fastened to the post 11b via an adhesive layer 7 which is, for example, Au(70%)Sn(30%) solder. In order to control reflectance, front and rear facet films (not shown) each made of a dielectric multilayer film are formed on front and rear facets of the nitride semiconductor light emitting element 3. The dielectric multilayer film includes a nitride film made of, for example, MN, BN, SiN, or the like, and an oxide film or an oxynitride film made of SiO₂, Al₂O₃, ZrO₂, AlON, or the like.

One of the electrodes of the nitride semiconductor light emitting element 3 is electrically connected to the lead pin 14a by a metal wire 40a, and the other of the electrodes is electrically connected to the lead pin 14b via the metal multilayer film on the surface of the submount 6 by a metal wire 40b.

As illustrated in FIG. 2A, the cap 30 includes a cylindrical metal cap 31 made of, for example, Kovar, an Fe:Ni alloy (e.g., 42 alloy), or iron, and a light transmitting window 32 fixed to the cylindrical metal cap 31 by a joint layer 33 made of low-melting point glass. Specifically, the metal cap 31 includes a cylindrical part 31a, a window fixing part 31b at which the light transmitting window 32 is fixed, and a light extraction opening 31d. On the other hand, the metal cap 31 has a flange part 31c facing the package 10. The flange part 31c extends outward so that the metal cap 31 can be easily welded to the base table 11. The light transmitting window 32 is an optical glass plate made of, for example, BK7, an anti-reflection film being formed on a surface of the optical glass plate. The joint layer 33 is made of, for example, low-melting point glass. The nitride semiconductor light emitting element 3 is enclosed by the cap 30 and the package 10, and, for example, a sealing gas 45 which is a mixed gas of oxygen and nitrogen is filled in the space enclosed by the cap 30 and the package 10.

With this configuration, a current 61 is applied to the nitride semiconductor light emitting element 3 from a power supply disposed outside as illustrated in FIG. 2A via interconnects connected to the lead pins 14a, 14b, so that outgoing light 70 which is light having a wavelength in the range, for example, from 390 nm to 500 nm i.e., from the ultraviolet region to the blue light region is output from the nitride semiconductor light emitting element 3 in a direction of a main light ray 70a. Here, Joule heat generated by the nitride semiconductor light emitting element 3 is transferred from the nitride semiconductor light emitting element 3 through the submount 6 and the post 11b to the base 11a as indicated by a heat dissipation route 80 in FIG. 2B, and is then released through a contact surface 55 to a fixing tool 50, i.e., to the outside.

Subsequently, a method for fabricating the semiconductor light emitting device of the present example will be described with reference to FIGS. 3A-3E. First, a welding table 11d, lead pins 14a, 14b, and a ground lead pin 15 are fastened to a base 11a of a package 10 of the present example under a temperature as high as for example, about 1000° C. by using a high-temperature furnace. Specifically, as illustrated in FIG. 3A, for example, oxygen-free copper is molded by using a die, thereby integrally forming the base 11a, a post 11b, and openings 11c to obtain a base table 11. Then, a molded product made of silver solder and serving as an adhesive layer 11e and the welding table 11d are disposed on the base table, and further, glass rings 18a, 18b and the lead pins 14a, 14b are sequentially disposed in the openings 11c. After that, in the high-temperature furnace, the adhesive layer 11e, the glass rings 18a, 18b, the lead pins 14a, 14b, and the ground lead pin 15 are fused with the base 11a.

Next, as illustrated in FIG. 3B, a shield member is formed by using a dispenser to cover the glass rings 18a, 18b. Specifically, for example, 0.1 cc of, for example, polyamide acid 19 which is a precursor of a polyimide resin serving as the shield member is dropped by using a needle 90 to cover a surface of each of the glass rings 18a, 18b on an identical side as a side of the base 11a on which the nitride semiconductor light emitting element will be disposed. At this time, before the polyamide acid is dropped, the package 10 is subjected to O₂ ashing, which can improve the wettability of the polyamide acid to the package. Thus, it is possible to increase the adherence of shield members 19a, 19b to the glass rings 18a, 18b, respectively and to the base 11a. Then, in a baking furnace, the package is baked in an environment of, for example, 180° C. for about one hour to imidize the polyamide acid, thereby obtaining polyimide. In this way, the shield members 19a, 19b are formed. The package 10 provided with insulating members 17a, 17b including the thus formed shield members 19a, 19 is fabricated.

Subsequently, as illustrated in FIG. 3C, a side of the package 10 on which a post 11b will be provided is subjected to an ashing process in ozone for a predetermined period, thereby removing an organic substance containing Si—O bonds.

Subsequently, as illustrated in FIG. 3D, a submount 6 and a nitride semiconductor light emitting element 3 are sequentially fastened to the post 11b of the package 10, and metal wires 40a, 40b are respectively attached to the nitride semiconductor light emitting element 3 and the submount 6. Specifically, the submount 6 used here is provided with Au(70%)Sn(30%) adhesive layers 5, 7 (metal multilayer films; not shown) formed in advance respectively on a surface of the submount 6 to which the nitride semiconductor light emitting element will be mounted and a surface of the submount 6 which will be in contact with the post 11b. The submount 6 and the nitride semiconductor light emitting element 3 are sequentially disposed on the post 11b, and the temperature of the package 10 is increased to about 300° C. Due to the temperature rise, the adhesive layers 5, 7 formed on the submount 6 are melted, so that the post 11b is electrically and thermally connected to the metal multilayer film on the lower surface of the submount 6, and the metal multilayer film on the upper surface of the submount 6 is electrically and thermally connected to the nitride semiconductor light emitting element 3. Here, the shield members 19a, 19b are heated to about 300° C. In the present example, the polyimide resin having a heat resistant temperature of the above-described 300° C. or higher is used, so that the shield members 19a, 19b are not deteriorated. Thereafter, for example, by using the plurality of metal wires 40a, 40b which are Au wires, the nitride semiconductor light emitting element 3 is electrically connected to the lead pins 14a, 14b.

Subsequently, as illustrated in FIG. 3E, a cap 30 is disposed at an upper portion of the package 10 in a predetermined atmosphere and is fixed by using a fixing table 91a and a presser 91b, and a predetermined current is applied to weld the welding table 11d to the cap 30 by means of a projection 31e, thereby achieving hermetic sealing. At this time, the cap 30 is produced by the following fabrication method. First, a material, for example, Kovar, or the like whose thermal expansion coefficient is close to that of glass is pressed, thereby forming a tubular metal cap in which a light extraction opening 31d is formed and which has a flange part 31c. At the same time, the projection 31e used for welding is formed at the flange part 31c. Next, a light transmitting window 32 is fixed to a window fixing part 31b by a joint layer 33 which is, for example, low-melting point glass. The light transmitting window 32 is, for example, a glass plate on the surface of which an anti-reflection film having low reflectance with respect to the wavelength of light emitted from the nitride semiconductor light emitting element 3 is formed.

With the above-described fabrication method, the nitride semiconductor light emitting device of the present example can be easily fabricated.

Next, in order to examine the effect of the present example, a nitride semiconductor light emitting device of the present example and a nitride semiconductor light emitting devices for comparison were actually fabricated, and the characteristics of and a long-term operation test performed on the nitride semiconductor light emitting devices were evaluated. With reference to FIGS. 4, 5A, and 5B, results of the examination by comparison will be described below.

First, the present inventors fabricated four types of nitride semiconductor light emitting devices as illustrated in FIG. 4 as first to fourth comparative examples, and conducted the long-term operation test to evaluate a variation in the characteristics of the nitride semiconductor light emitting devices.

Packages each having a base whose material is steel and a post whose material is oxygen-free copper but having no shield member (first and second comparative examples) and packages each having a base and a post both made of oxygen-free copper similar to the present example but having no shield member to expose glass rings (third and fourth comparative examples) were fabricated. AlN ceramic is mounted to a submount of each of the packages (the first and third comparative examples), and SiC ceramic is mounted to a submount of each of the packages (the second and fourth comparative examples). As described in the above fabrication method, the packages are configured such that the nitride semiconductor light emitting element, the submount, and the post are fastened to each other by Au(70%)Sn(30%) solder, and before performing hermetic sealing by welding a cap, a Si organic compound gas is removed by ozone, so that no Si organic compound gas is generated in a hermetically enclosed environment in which the nitride semiconductor light emitting element is disposed.

First, with this configuration, the heat resistance of the nitride semiconductor light emitting devices having bases made of steel (the first and second comparative examples) and the heat resistance of the nitride semiconductor light emitting devices having bases made of oxygen-free copper (the third and fourth comparative examples) were compared with each other. As a result, it was found that the heat resistance of the nitride semiconductor light emitting devices having bases made of oxygen-free copper was about 20% lower than that of the nitride semiconductor light emitting devices having bases made of steel.

Subsequently, the hermeticity was examined by inspection for a leak of a helium gas. In the present example and in the first and second comparative examples, the amount of leak was less than or equal to 10⁻⁹ Pa·m³/sec, and in the third and fourth comparative examples, the amount of leak was 10⁻⁷-10⁻⁹ Pa·m³/sec.

Next, the nitride semiconductor light emitting devices of the present example and the first to fourth comparative examples were subjected to the long-term operation test. The operation test was conducted under the conditions that the base temperature was 50° C. and the optical output was 2 W for continuous wave operation (CW). Time-dependency of specific optical output is shown in FIG. 5. In the third and fourth comparative examples, the optical output was rapidly reduced between 200-500 hours.

In order to analyze the cause of this rapid reduction, the nitride semiconductor light emitting devices were decomposed. A large amount of SiO₂ was deposited on the front facet film of the nitride semiconductor light emitting element of the nitride semiconductor light emitting device of each of the third and fourth comparative examples. This shows the phenomena in which when the nitride semiconductor light emitting element 3 is operated to output light having a very high optical density from the front facet film, a large amount of SiO₂ is deposited at a light output section in the case of the long-term operation, which rapidly deteriorates the characteristics of the nitride semiconductor light emitting element 3. In FIG. 4, the deposition rate is 16-17 nm/second, where the rate is computed based on the thickness of the deposit obtained by cross-sectional TEM analysis. Moreover, operation of the first and second comparative examples was also stopped, the nitride semiconductor light emitting devices were decomposed, and the front facet film of each of the nitride semiconductor light emitting elements was analyzed. It was found that SiO₂ was deposited although the amount of the SiO₂ was less than that in the third and fourth comparative examples. However, as described above, in the configurations of the first to fourth comparative examples evaluated this time, the Si organic compound gas which has been described in the conventional technique and causes deposition of SiO₂ is not generated in the sealing gas.

Therefore, the present inventors inspected for causes of the generation of SiO₂. For the deposition of SiO₂ on the front facet film of the nitride semiconductor light emitting element, at least Si must be floating in any form in an atmospheric gas. Here, members which may be causes of the generation of Si are the submount, the glass ring, and the low-melting point glass for fixing the light transmitting window. However, an anti-reflection film which is a dielectric multilayer film containing no Si was formed on a surface of glass of which light transmitting windows of the comparative examples were made. Thus, the glass was excluded from the causes.

First, the result of comparison between the first and second comparative examples and the result of comparison between the third and fourth comparative examples show that whether the base material of the submount is SiC ceramic containing Si or AlN ceramic containing no Si results in no significant difference. Thus, it was found that the submount was not the cause. Next, in order to determine whether or not a gas containing Si is generated from the glass ring, a package shown as the first example in FIG. 4 and having the same base, post, glass ring, and submount material as those of the fourth comparative example was further coated with a polyimide resin to cover the glass ring to fabricate a nitride semiconductor light emitting device, and the nitride semiconductor light emitting device was subjected to the long-term operation test. As a result, as illustrated in FIG. 5A, the optical output of each of two samples (n=2) of the fourth comparative example was rapidly reduced in less than 500 hours. In contrast, as illustrated in FIG. 5B, in the present example, the rapid reduction in optical output did not occur for over 1500 hours. After 1500 hours, the nitride semiconductor light emitting device was decomposed. A small amount of SiO₂ was generated, but in comparison with the fourth comparative example, the amount of SiO₂ was significantly reduced. Thus, it is concluded that the gas, which is a cause of SiO₂ generated in the first to fourth comparative examples and deposited on the front facet film of the nitride semiconductor light emitting element was generated from the glass ring. The low-melting point glass for fixing the light transmitting window is also a member containing Si, but when the configuration around the glass ring is modified, the amount of the deposit is significantly changed. Thus, the degree of contribution of the low-melting point glass to the generation of the gas can be considered low.

The phenomena described above can be summarized as (1)-(3) below. (1) Of SiO₂ materials present in the package, only a SiO₂ material close to the base generates the gas. (2) The gas is not generated from a SiC material containing no O. (3) Three differences between the SiO₂ material close to the cap and the SiO₂ material close to the base are (a) the metal material with which the SiO₂ material is in contact, (b) the temperature during operation, and (c) applied field (between the base and the lead pin) during operation.

In the foregoing, although the mechanism of the phenomena which were found in the experiment and in which any Si compound generated from the glass ring floats in the atmospheric gas and is deposited on the light output section of the semiconductor light emitting element is not clear, the present inventors consider that the gas containing Si is generated from the glass ring based on the following two mechanisms.

(a) Reaction between metal of which the base is made and the glass ring generates the gas containing Si—O from the glass ring.

(b) The generation of the gas is accelerated by heat generated by the nitride semiconductor light emitting element or an electric field applied to the space between the base and the lead pin.

On the other hand, in the present example, the glass rings 18a, 18b are covered with the shield members 19a, 19b having high gas barrier properties. Thus, it is assumed that entry of the gas was blocked by the shield members even when the gas was generated from the glass ring, so that it was possible to reduce deterioration of the characteristics of the nitride semiconductor light emitting element 3.

Moreover, in the present experiment, the thermal resistances of the nitride semiconductor light emitting devices of the first to fourth comparative examples having bases made of different materials were also compared with each other. As a result, the thermal resistance of the nitride semiconductor light emitting devices having bases made of oxygen-free copper as in the present example was 20% lower than that of the nitride semiconductor light emitting devices having bases made of steel. Moreover, these nitride semiconductor light emitting devices were subjected to the long-term operation test under the same conditions and compared with each other. As a result, it was found that the difference in the thermal resistance significantly influences the life of the nitride semiconductor light emitting device. That is, a reduction in optical output is greater in the nitride semiconductor light emitting device having the base whose material is steel than in the nitride semiconductor light emitting device having a base whose material is oxygen-free copper. This is because due to the difference in thermal resistance, the temperature of the nitride semiconductor light emitting element during operation is higher in the case of the base made of steel. That is, as described in the present example, the base is made of oxygen-free copper, and the shield members 19a, 19b are further provided, so that deterioration in characteristic due to adhesion of substances to light output facet of the nitride semiconductor light emitting element 3 and due to the temperature rise can be reduced, and thus, this configuration is more preferable.

Subsequently, results of study on materials and forming methods of an insulating member of the present embodiment will be described with reference to FIGS. 6A and 6B. First, to fabricate a package of the present example, the base, the glass ring, and the lead pin are assembled, and then, the assembly is kept under a high temperature of about 1000° C. close to the melting point of the glass ring as described with reference to FIG. 3A so that the base, the glass ring, and the lead pin are adhered to each other. As a material of the insulating member, an insulative inorganic material containing no Si—O bond was considered other than the glass ring. Specifically, metal oxide (e.g., Al₂O₃) and metal nitride (e.g., Si₃N₄) were considered other than the low-melting point glass (SiO₂). As a result, it was found that low-melting point glass (SiO₂) to which barium oxide or the like has been added is the most suitable material of the insulating member because other materials have a high melting point or a low degree of adhesiveness to metal forming the base. However, in order to reduce generation of the gas, a material containing no Si—O bond is required. Thus, covering the glass ring with a shield member containing no Si—O bond was considered. In addition to the insulative inorganic material, insulative organic materials such as a thermoplastic resin and a thermosetting resin were also considered as a material of the shield member.

Requirements for such resin materials are, first of all, being impervious to the gas generated by the glass ring (gas permeability) in order to prevent deterioration of the nitride semiconductor light emitting element, and containing no Si—O bond in order not to generate the gas containing Si—O bonds. Moreover, the heat resistance against a mounting temperature at the time of mounting the nitride semiconductor light emitting element after providing the shield member to the package has to be taken into consideration. For example, when mounting is performed by using AnSn eutectic solder as the adhesive layer, a temperature equal to or higher than 300° C. which is higher than the eutectic temperature of the adhesive layer is applied to the shield member. Thus, the shield member is required to have heat resistance so that none of expansion, crack, deformation, and decomposition occurs even when a temperature higher than the eutectic temperature of the adhesive layer is applied to the shield member. Therefore, a material forming the shield member preferably has heat resistance against the eutectic temperature or the melting point of the adhesive layer. Specifically, the material preferably has a heat resistant temperature of equal to or higher than 300° C. The results of the study on the above-described items are shown in FIG. 6A as a list of characteristics of materials forming the shield member. Here, as an index with which the heat resistance (heat resistant temperature) is compared, the glass transition temperature, the melting point, and the thermal decomposition temperature are used.

Subsequently, with reference to FIG. 6B, results of study on the method for forming the shield member of the present embodiment will be described. It is important for a package used for the nitride semiconductor light emitting device illustrated in the present example that electric connection is taken into consideration in addition to high heat dissipation. That is, in order to efficiently release Joule heat generated in the nitride semiconductor light emitting element via the post, and in order to easily establish an electrical connection between the nitride semiconductor light emitting element and the lead pin, the shield member has to be locally formed near the glass ring. Specifically, because the thermal conductivity of the shield member made of an insulating material is lower than that of the submount or the post used in the present example, the heat dissipation is deteriorated if the shield member is disposed between the post and the submount. This leads to the deterioration of the characteristics of the nitride semiconductor light emitting element. Moreover, since the mechanical strength of connection is reduced, there may be a case where the connection itself becomes difficult. Furthermore, the lead pins have to be electrically connected to the nitride semiconductor light emitting element and the submount via wires, but the electrical connection becomes impossible if the shield member which is an insulator covers the lead pins. Thus, it is preferable to locally form the shield member only near the glass rings.

In order to prevent the Si-containing gas generated by the glass ring from entering the package, the shield member is preferably a dense film having a certain thickness. Moreover, when the shape of the package and the unevenness of the glass ring itself are taken into consideration, the shield member preferably has a thickness of about several tens of μm.

Results obtained by comparing methods for forming the shield member with each other based on the items studied above are shown in FIG. 6B. First, for example, for a vacuum deposition method such as vapor deposition, locally forming the shield member is difficult. Moreover, the thickness of a film which can be formed at one time of film formation is about several μm. Therefore, the film formation and patterning have to be repeated, which complicates steps and increases fabrication costs. Similar to the case of the vacuum deposition method, locally forming the shield member is difficult for a solvent extracting method such as a sol-gel method. On the other hand, a coating method used in the present example is a method in which a substance in a liquid state is applied to a desired position by a pipette, a device for discharging a fixed quantity of liquid (dispenser), or the like, thereby forming a desired volume of a film. Therefore, this method is applicable to the package of the present example having a complicated shape. Thus, the coating method is mentioned as a preferable method for forming the shield member.

Next, FIG. 6C shows comparison of materials of the adhesive layer studied for fastening the nitride semiconductor light emitting element and the submount to the post. Selecting suitable metal or a metal alloy forming the adhesive layer can change the mounting temperature. As described above, the heat resistant temperature of the material forming the shield member is preferably higher than the eutectic temperature or the melting point of the adhesive layer. For example, a configuration in which In is included as the adhesive layer and an epoxy resin (which does not contain a material, e.g., siloxane, containing Si—O bond) is included as the shield member is also possible. The most preferable embodiment includes a combination of Au(70%)Sn(30%) as the adhesive layer and a polyimide resin as the shield member.

(First Variation of the First Example)

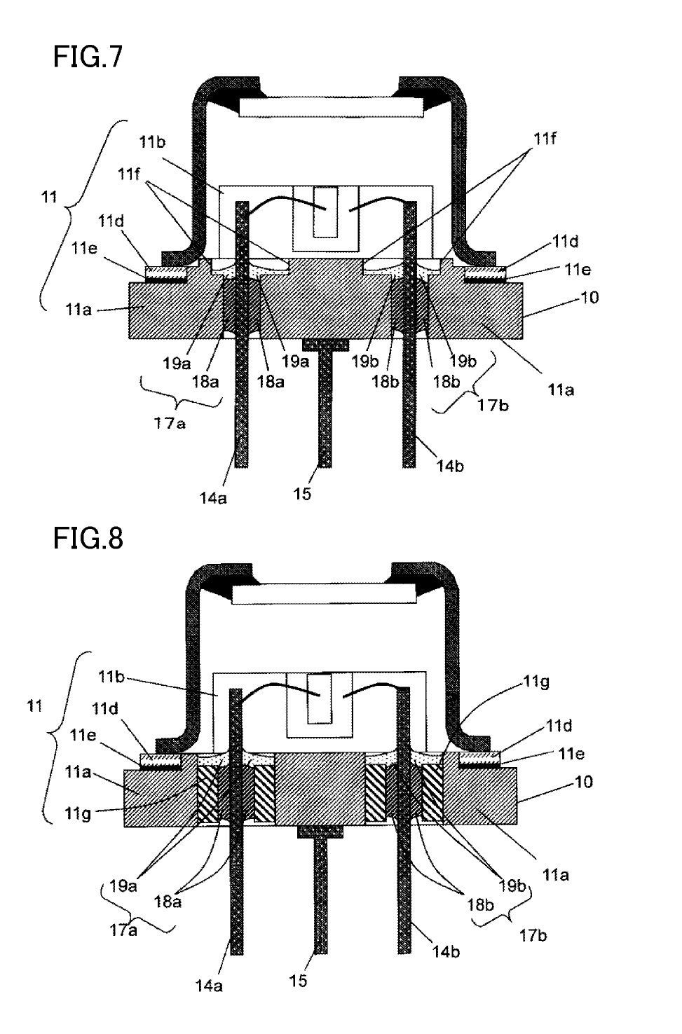

Subsequently, with reference to FIG. 7, a nitride semiconductor light emitting device of a first variation of the first example will be described. FIG. 7 is a cross-sectional view schematically illustrating the nitride semiconductor light emitting device according to the first variation of the first example. The same reference numerals as those shown in the first example are used to represent equivalent elements, and the explanation thereof will be omitted.

The shape of each of openings 11c of a base 11a of the nitride semiconductor light emitting device of the first variation illustrated in FIG. 7 is significantly different from that of the nitride semiconductor light emitting device of the first example. Specifically, the opening 11c is structured to have a greater opening diameter around a shield member serving as a first insulating member than around a glass ring serving as a second insulating member. That is, at a portion of the opening 11c facing the post, a side flow preventer 11f having a greater opening diameter than the other portions of the opening 11c is formed. Providing the side flow preventer 11f can prevent polyamide acid 19 from flowing over a peripheral portion of the opening 11c even when the amount of the polyamide acid 19 is increased due to an accuracy error of the amount of application by a dispenser when the polyamide acid 19 is applied by the dispenser and a needle. Thus, a reduction in hermeticity, which is caused by defective welding between a cap 30 and a package 10 due to a flow of the polyamide acid 19 to a joint position of the base table 11 to the cap 30, can be prevented. Moreover, forming the side flow preventer 11f can increase the contact area and improve the adhesiveness between the base 11a and shield members 19a, 19b. Thus, it is possible to prevent a gas generated by glass rings 18a, 18b from passing through the gaps between the base 11a and the shield members 19a, 19b.

In addition to the structure of the first variation, the region of each side flow preventer 11f may be expanded so that the glass ring 18a and the glass ring 18b are surrounded by one side flow preventer 11f. In this case, the number of application of the shield member can be reduced to one, which simplifies steps and reduces fabrication costs. In particular, for example, the wettability of the polyamide acid is adjusted, and the polyamide acid is dropped to the side flow preventer 11f between lead pins 14a, 14b so that the polyamide acid extends over and cover the glass rings 18a, 18b. With this fabrication method, the position of the needle and the position of application of the polyamide acid can be easily set.

Moreover, surfaces of the glass rings 18a, 18b facing the post and a surface of the side flow preventer 11f may have uneven structures. With this configuration, the surfaces of the glass rings 18a, 18b facing the post and the surface area of the side flow preventer 11f are increased, so that the adhesiveness between the polyimide resin and the base can be further increased.

(Second Variation of the First Example)

FIG. 8 is a cross-sectional view schematically illustrating a nitride semiconductor light emitting device according to a second variation of the first example. The same reference numerals as those shown in the first example are used to represent equivalent elements, and the explanation thereof will be omitted. A package 10 of the second variation includes a metal ring 11g provided in each of openings 11c and made of a material different from a material forming a base 11a. Lead pins 14a, 14b are fixed to the openings 11c of the base via glass rings and the metal rings. Here, the glass ring and the metal ring are disposed in this order from the lead pin. With this configuration, the metal ring can be made of a material different from a material forming the base. Thus, the metal rings can be made of a metal material, for example, steel which reduces a gas containing Si—O bonds and generated by the glass rings.

### Second Example

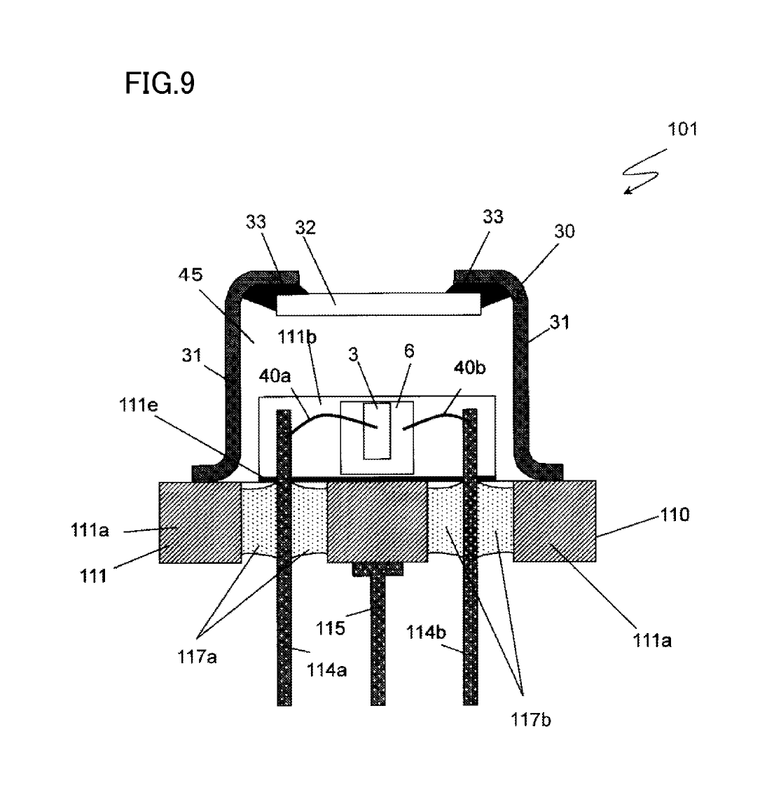

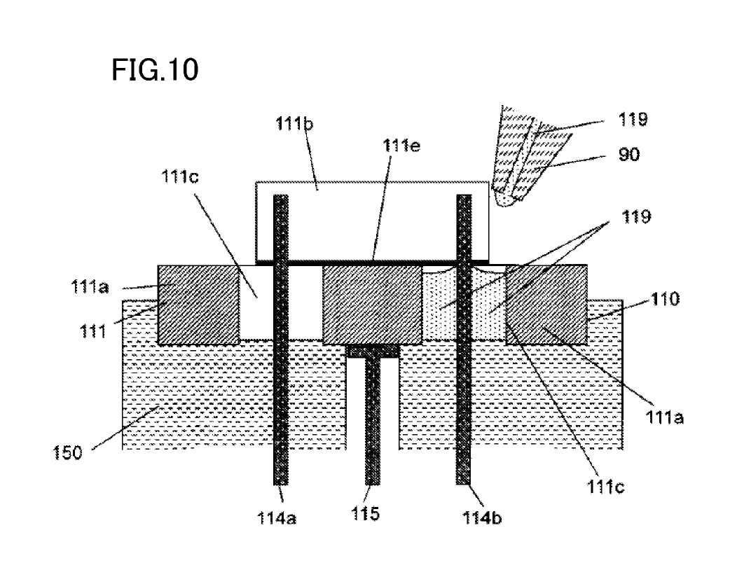

Subsequently, with reference to FIGS. 9 and 10, a nitride semiconductor light emitting device according to a second example will be described. FIG. 9 is a cross-sectional view schematically illustrating the nitride semiconductor light emitting device according to the second example. FIG. 10 is a view illustrating a method for fabricating the nitride semiconductor light emitting device according to the second example. A feature of insulating members 117a, 117b of the present example is that a material forming the insulating members 117a, 117b is only an insulating material containing no Si—O bond, for example, a polyimide resin.

A configuration of a nitride semiconductor light emitting device 101 of the present example will be described below with reference to FIG. 9. The same reference numerals as those shown in the first example are used to represent equivalent elements, and the explanation thereof will be omitted. In a package 110 of the present example, steel is used as a material of a base 111a and oxygen-free copper is used as a material of a post 111b. The base 111a and the post 111b are fastened to each other by an adhesive layer 111e which is, for example, silver solder. With this configuration, when a cap 30 is welded to the package 110, it is not necessary to prepare a welding table.

Subsequently, a method for fabricating the package 110 of the nitride semiconductor light emitting device 101 of the present example will be described with reference to FIG. 10. First, the post 111b and a ground lead pin 115 which are made of oxygen-free copper are fastened to predetermined positions of the base 111a made of steel by, for example, the adhesive layer 111e which is silver solder. An assembly obtained by fastening the base 111a, the post 111b, and the ground lead pin 115 to each other is subjected to a surface process using Ni, Au, or the like in a plating bath. Subsequently, lead pins 114a, 114b are subjected to a surface process in a similar manner by plating, or the like. Subsequently, to a fixing tool 150 in which predetermined openings have been formed, the assembly is fixed with the positions of the base 111a and the lead pins 114a, 114b being precisely adjusted to the openings. By using a needle 90, a predetermined amount of polyamide acid 119 which will be insulating members 117a, 117b is dropped to openings 111c. Then, the assembly fixed to the fixing tool 150 is inserted in an annealing furnace in which the temperature is for example, about 180° C. so that the polyamide acid 119 is hardened. At this time, the fixing tool 150 fixes the base 111a and the lead pins 114a, 114b such that the lead pins 114a, 114b each keep a predetermined distance to the base 111a so that the base 111a and the lead pins 114a, 114b are not electrically in contact with each other. The package 110 is fabricated in the above-described fabrication method. Thereafter, in a similar manner to the first example, a nitride semiconductor light emitting element 3, a submount 6, and the cap 30 are attached to the package 110.

With this configuration, an insulating member made of a material containing no Si—O bond and having excellent hermeticity can be used for the insulating members 117a, 117b. Thus, the nitride semiconductor light emitting device can be more easily configured and deterioration of the nitride semiconductor light emitting device in the case of long-term operation can be prevented.

In the present example, the package material is not limited to those described above, but similar to the first example, a package including a base 111a and a post 111b integrally molded from oxygen-free copper and a welding table may be used.

In the present example, polyimide has been used for the insulating members 117a, 117b, but an insulative inorganic material containing no Si—O bond may be used. Specifically, metal oxide (e.g., Al₂O₃) or metal nitride (e.g., Si₃N₄) can be used.

### Third Example

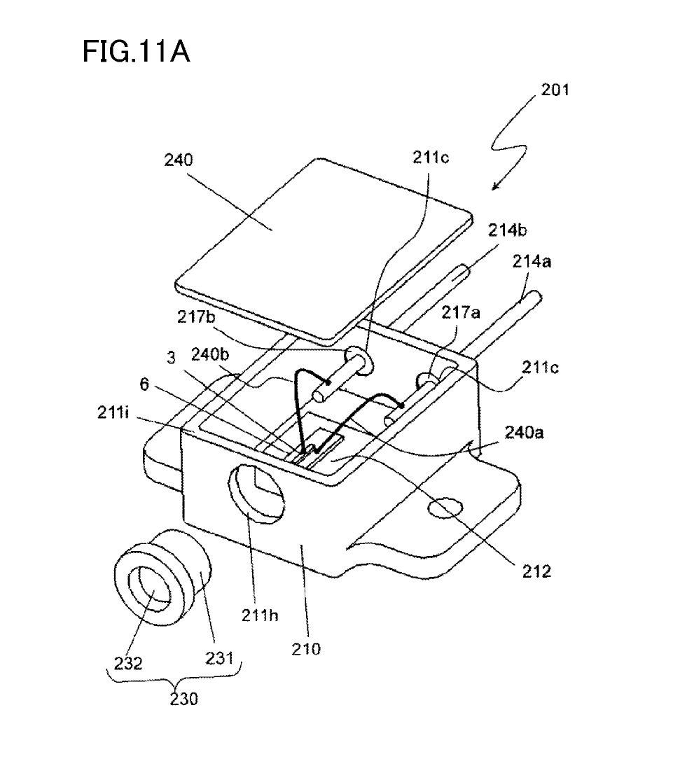

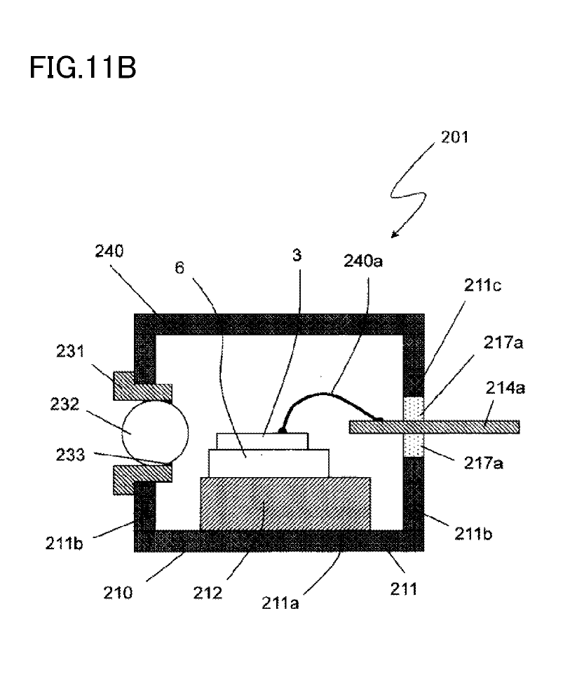

Subsequently, with reference to FIGS. 11A and 11B, a nitride semiconductor light emitting device according to a third example will be described. FIG. 11A is an exploded perspective view of the nitride semiconductor light emitting device according to the third example. FIG. 11B is a cross-sectional view schematically illustrating the nitride semiconductor light emitting device according to the third example. The same reference numerals as those shown in the first example are used to represent equivalent elements, and the explanation thereof will be omitted.

In the present example, a package 210 used in the nitride semiconductor light emitting device 201 is a package whose basic configuration is the same as that of a so-called butterfly-type package. The nitride semiconductor light emitting device 201 includes a carrier 212, a submount 6, and a nitride semiconductor light emitting element 3 which are sequentially stacked and fixed to a bottom surface of the package 210. A cap 230 is inserted in an opening 211h which is formed in the package 210 and from which light from the nitride semiconductor light emitting element 3 goes out. A lid 240 closes an opening 211i above an upper surface of the nitride semiconductor light emitting element 3. The package 210 includes a base 211a made of, for example, a copper tungsten alloy and disposed as a bottom surface of the package 210, and a side wall 211b surrounding the base 211a. The opening 211h in which the cap 230 will be inserted is formed in the sidewall 211b in a direction in which light from the nitride semiconductor light emitting element goes out, and openings 211c for fixing lead pins 214a, 214b are formed. The cap 230 includes a metal cap 231 and a lens glass 232 made of, for example, glass and fixed to the metal cap 231 by an adhesive layer 233 such as low-melting point glass. The lead pins 214a, 214b are fixed to center sections of the openings 211c respectively by insulating members 217a, 217b which are made of, for example, a polyimide resin.

With this configuration, an insulating member made of a material containing no Si—O bond and having excellent hermeticity can be used for the insulating members 217a, 217b. Thus, the nitride semiconductor light emitting device can be more easily configured, and deterioration of the nitride semiconductor light emitting device in the case of long-term operation can be prevented.

### Fourth Example

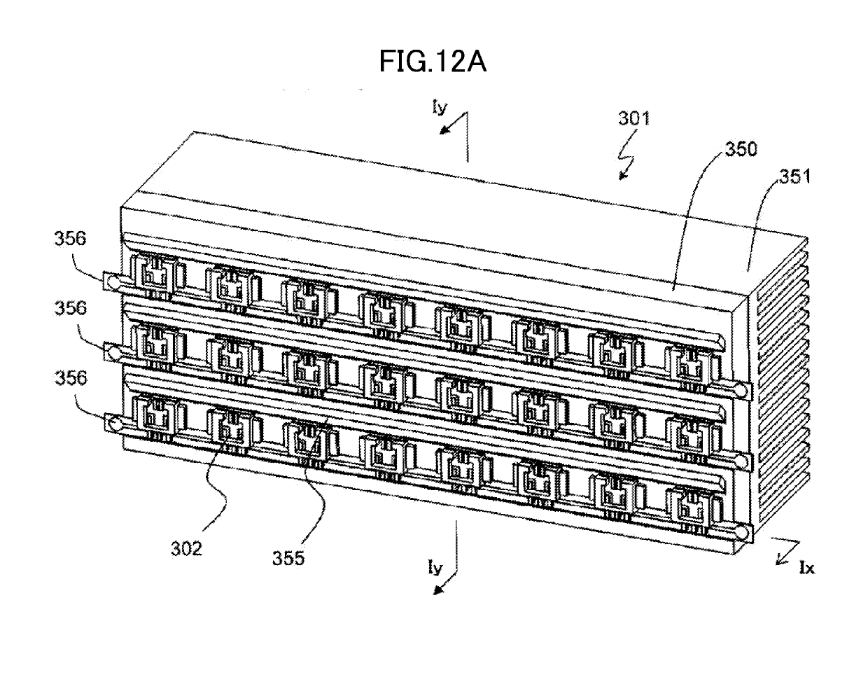

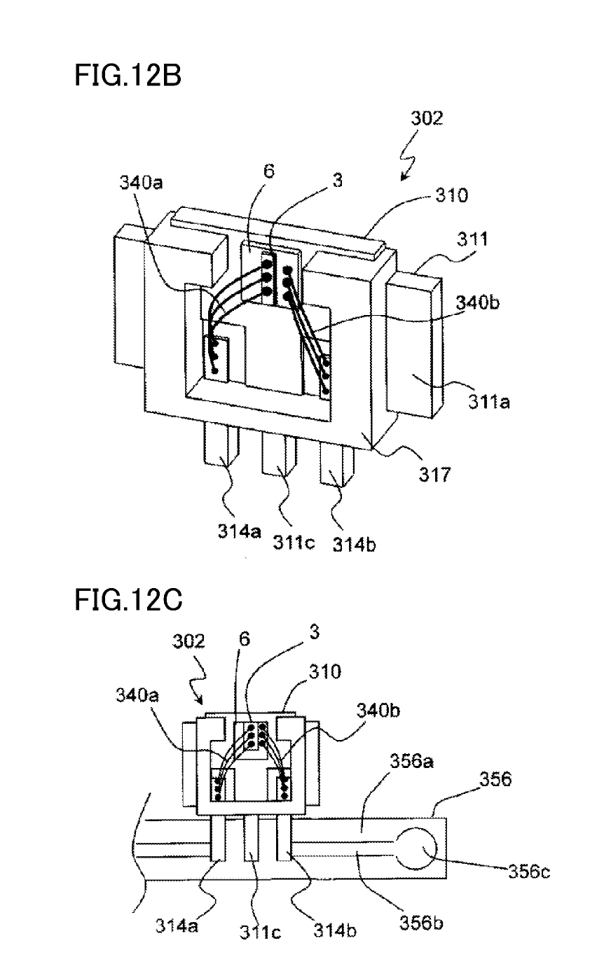

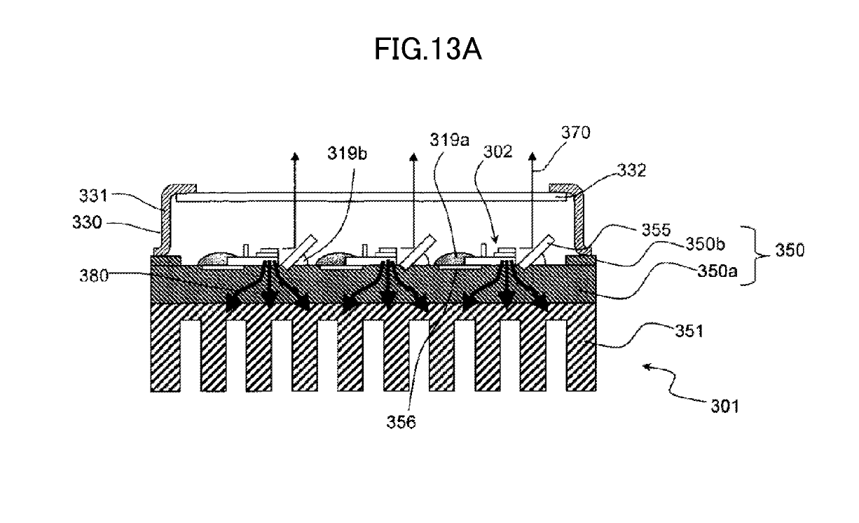

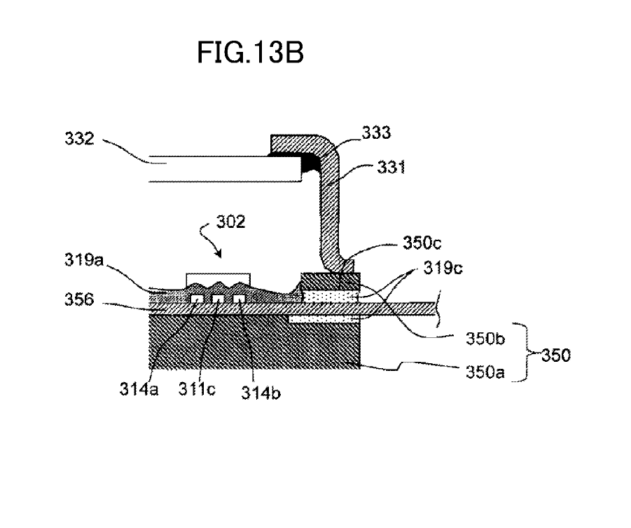

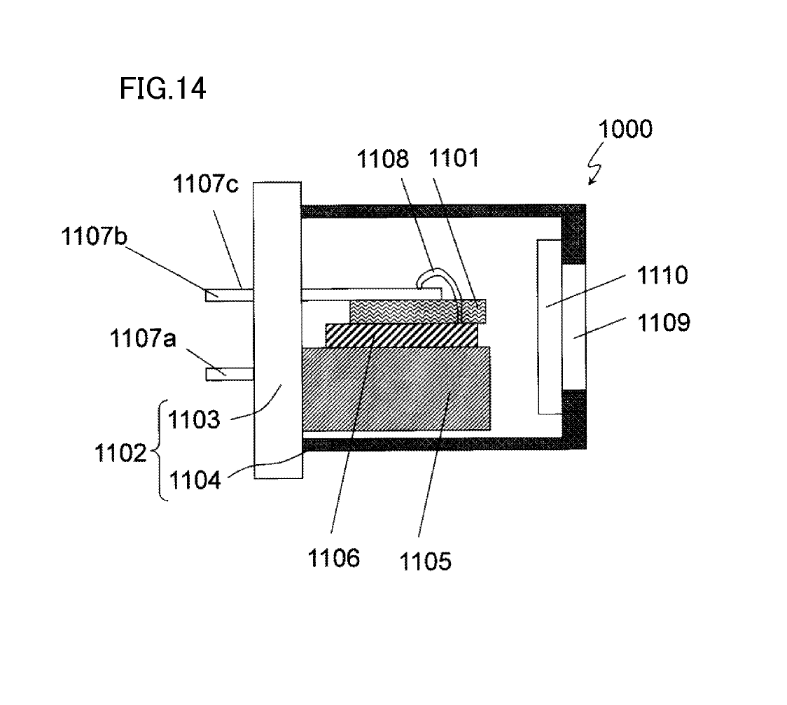

Subsequently, with reference to FIGS. 12A-12C and FIGS. 13A, 13B, a nitride semiconductor light emitting device according to a fourth example will be described. FIG. 12A is an exploded perspective view illustrating the nitride semiconductor light emitting device according to the fourth example, where a cap is removed. FIG. 12B is a perspective view illustrating a part of the nitride semiconductor light emitting device according to the fourth example. FIG. 12C is a top view illustrating a part of the nitride semiconductor light emitting device according to the fourth example. FIG. 13A is a cross-sectional view schematically illustrating the nitride semiconductor light emitting device according to the fourth example taken along the line Iy-Iy of FIG. 12A. FIG. 13B is a cross-sectional view schematically illustrating a part of the nitride semiconductor light emitting device according to the fourth example taken in the direction Ix of FIG. 12A. The same reference numerals as those shown in the first example are used to represent equivalent elements, and the explanation thereof will be omitted.

A nitride semiconductor light emitting device 301 of the present example includes a plurality of nitride semiconductor light emitting devices 302 arranged on a base table 350 provided with a heat sink 351. The base table 350 includes a heat spreader 350a made of, for example, copper and a presser (welding table) 350b made of an iron alloy such as Kovar and fixed to the heat spreader 350a along the circumference of the heat spreader 350a by welding, screwing, or the like.

As illustrated in FIG. 13A, the plurality of nitride semiconductor light emitting devices 302 are hermetically enclosed by the heat spreader 350a and a cap 330. Each nitride semiconductor light emitting device 302 includes a submount 6 and a nitride semiconductor light emitting element 3 which are mounted to a lead frame-shaped package 310. The package 310 includes a base table 311 and lead pins 314a, 314b which are integrally molded together with an insulating member 317. Electrical connections are provided to the nitride semiconductor light emitting element 3 and the submount 6 respectively by metal wires 340a, 340b.

Specifically, as illustrated in FIG. 12B, the base table 311 of the nitride semiconductor light emitting device 302 is a plate-like base table obtained by integrally forming a base 311a to which the submount 6 is to be mounted and a ground lead 311c. The base table 311 is obtained by molding a metal plate made of, for example, copper at the same time when the lead pins 314a, 314b are formed. The insulating member 317 holds the base table 311 and the lead pins 314a, 314b in an electrically insulating manner and is included in the package 310. Part of the insulating member 317 on a side on which the nitride semiconductor light emitting element 3 is mounted is formed to have a greater height than the metal wires 340a, 340b to protect the nitride semiconductor light emitting element 3 and the metal wires 340a, 340b. Here, the insulating member 317 is made of a material such as a polyimide resin containing no Si—O, and thus the deterioration of the nitride semiconductor light emitting element 3 can be prevented even when the insulating member 317 is disposed in the hermetically enclosed region of the nitride semiconductor light emitting device 301.

FIG. 12A is a perspective view illustrating the nitride semiconductor light emitting device 301, where the cap 330 is removed. In the present example, the nitride semiconductor light emitting device 301 including a laser array configured by having nitride semiconductor light emitting devices 302 in three rows and in eight columns, i.e., a total of 24 nitride semiconductor light emitting devices 302 will be described as an example. In the present example, the eight nitride semiconductor light emitting devices 302 in each row are connected to each other by a flexible printed circuit board 356 in series, and are arranged to be interconnected to an external circuit.

Specifically, as illustrated in the partial top view of FIG. 12C, the flexible printed circuit board 356 includes an insulating substrate 356a made of, for example, a polyimide resin, and an interconnect 356b made of, for example, copper foil patterned on the insulating substrate 356a, wherein an external terminal 356c which is to be connected to the external circuit is further formed at a terminal portion of the interconnect 356b. The flexible printed circuit board 356 serves as a lead for electrically connecting an enclosed space defined by the base table 350 and the cap 330 to the outside. The interconnect 356b is electrically connected to the lead pins 314a, 314b of the nitride semiconductor light emitting device 302 by a solder material such as SnAgCu.

As illustrated in FIG. 13A, a reflecting mirror 355 is each arranged on a side from which light from the eight nitride semiconductor light emitting devices 302 in each row goes out. Outgoing light 370 output in parallel to a surface of the heat spreader 350a from the nitride semiconductor light emitting device 302 is reflected by the reflecting mirror 355 in a vertical direction and output through a light transmitting window 332 to the outside. At this time, Joule heat generated by the nitride semiconductor light emitting element 3 is transferred through the heat spreader 350a directly under the nitride semiconductor light emitting device 302 and the heat sink 351 as indicated by heat dissipation routes 380, and is easily released to the outside.

On the other hand, the 24 nitride semiconductor light emitting devices 302 are enclosed by the cap 330. Similar to the first example, the cap 330 includes a metal cap 331 and a light transmitting window 332. The light transmitting window 332 is a glass plate which is made of, for example, BK7 and whose surface is provided with an anti-reflection film. The anti-reflection film is a dielectric multilayer film whose outermost surface is made of a film other than a SiO₂ film to reduce the reflectance of the wavelength of the light emitted from the nitride semiconductor light emitting element 3. Similar to the first example, the light transmitting window 332 is fastened to the metal cap 331 by a joint layer 333 which is low-melting point glass.

Here, in the space enclosed with the cap 330 and the heat spreader 350a, an area close to the heat spreader 350a is filled with metal or an insulating material containing no Si—O bond. For example, the insulating substrate 356a of the flexible printed circuit board 356 is made of a material containing no Si—O bond or is covered with a shielding material containing no Si—O bond. For example, the insulating substrate 356a of the flexible printed circuit board 356 is made of a polyimide resin containing no impurity containing Si—O bonds. The interconnect 356b is adhered to the insulating substrate 356a by an adhesive containing no Si—O bond.

When a flexible printed circuit board 356 containing material containing Si—O bonds is used, a resin containing no Si—O bond, for example, a shield member 319a which is, for example, a polyimide resin as illustrated in FIG. 13A covers a surface of the flexible printed circuit board 356. Moreover, a fixing member 319b for fixing the reflecting mirror 355 is also made of an insulating material containing no Si—O bond. Furthermore, the cap 330 and the presser (welding table) 350b of the base table 350 are connected to each other by welding as in the first example or fixed to each other by sealing with an insulating material containing no Si—O bond. As illustrated in FIG. 13B, the flexible printed circuit board 356 extends through an opening 350c of the base table 350, that is, the opening 350c formed between the heat spreader 350a and the presser 350b. Moreover, the opening 350c is closed by a sealing member 319c which is for example, a polyimide resin. With this configuration, the nitride semiconductor light emitting elements 3 are disposed between the cap 330 and the base table 350, and the nitride semiconductor light emitting devices 302 can be enclosed with the insulating material containing no Si—O bond. When an insulating material containing Si—O bonds is used as the sealing member 319c, the sealing member 319c is covered with the shield member 319a as illustrated in FIG. 13B, so that the configuration of the present disclosure can be realized.

As described above, according to the configuration of the present example, a surface of an inner wall hermetically enclosing space in the nitride semiconductor light emitting device 301 can be made of metal or an insulating material containing no Si—O bond and having excellent hermeticity. Therefore, a nitride semiconductor light emitting device having high optical output can be more easily configured, and deterioration of the nitride semiconductor light emitting device in the case of long-term operation can be prevented.

In the first and second examples, the package has two lead pins and one ground lead pin, but the present disclosure is not limited to this configuration. For example, the base can be fixed to an external fixing tool for grounding, so that no ground lead pin is required. The nitride semiconductor light emitting element which will be mounted to the nitride semiconductor light emitting device can be a semiconductor laser array element having a plurality of waveguides and can be provided with three or more lead pins, and wires each can be bonded to a corresponding one of the waveguides. In this case, all of the plurality of lead pins are provided with the shield members, so that the deterioration of the nitride semiconductor light emitting element can be more effectively reduced.

The nitride semiconductor light emitting element is

a nitride semiconductor-based high-power semiconductor laser element which has an emission wavelength in the range from 380 nm to 500 nm and whose optical output exceeds 1 watt in each of the first to third examples, and
the nitride semiconductor light emitting element is
a nitride semiconductor-based high-power laser array which has an emission wavelength in the range from 380 nm to 500 nm and whose optical output exceeds 1 watt in the fourth example.

However, in each of the first to third examples, the laser array may be used, and in the fourth example, the semiconductor laser element may be used.

The nitride semiconductor light emitting element can be a nitride semiconductor-based super luminescent diode, or the like suitable for image display devices and having low speckle noise.

The semiconductor light emitting device and the light source of the present disclosure are particularly useful as light sources of devices requiring relatively high optical output, such as image display devices including a laser display and a projector, and an industrial laser apparatus for laser processing or laser annealing.

What is claimed is:

1. A nitride semiconductor light emitting device comprising:
a nitride semiconductor light emitting element; and
a package in which the nitride semiconductor light emitting element is accommodated, wherein
the package includes
a base table which holds the nitride semiconductor light emitting element and in which an opening is formed;
a cap fixed to the base table to define an accommodation space for accommodating the nitride semiconductor light emitting element together with the base table,
a lead pin passing through the opening and electrically connected to the nitride semiconductor light emitting element, and
an insulating member filled in the opening to insulate the base table from the lead pin, and
at least part of the insulating member which is located on an accommodation space side is made of a first insulating material containing no Si—O bond.

2. The nitride semiconductor light emitting device of claim 1, wherein
the first insulating material is a resin.

3. The nitride semiconductor light emitting device of claim 1, wherein
the first insulating material has a heat resistant temperature of 300° C. or higher.

4. The nitride semiconductor light emitting device of claim 1, wherein
the first insulating material is polyimide.

5. The nitride semiconductor light emitting device of claim 1, wherein
the insulating member includes a first insulating member made of the first insulating material and a second insulating member made of glass, and
on the accommodation space side, the first insulating member covers the second insulating member.

6. The nitride semiconductor light emitting device of claim 5, wherein
the opening has a first portion on the accommodation space side and a second portion whose diameter is smaller than a diameter of the first portion, and
the first insulating member is embedded in the first portion, and the second insulating member is embedded in the second portion.

7. The nitride semiconductor light emitting device of claim 1, wherein
the base table is made of oxygen-free copper.
